(19) United States
(12) Patent Application Publication
(10) Pub. No.: US 2023/0242007 A1
(43) Pub. Date: Aug. 3, 2023

(54) SHORT-TERM STORAGE BASED ON STATE-OF-CHARGE FOR ELECTRIC VEHICLES

(71) Applicant: FORD GLOBAL TECHNOLOGIES, LLC, Dearborn, MI (US)

(72) Inventors: Caitlyn Cavanagh, Redwood City, CA (US); Chi Paik, Grosse Ile, MI (US); Deborah E. Callicoat, Livonia, MI (US); Jacqueline Jammoul, Canton, MI (US)

(21) Appl. No.: 17/589,636

(22) Filed: Jan. 31, 2022

(51) Int. Cl. B60L 58/13; H02J 7/00; B60L 53/63

(52) U.S. Cl. CPC B60L 58/13; H02J 7/0071; H02J 7/0049; H02J 7/005; B60L 53/63; B60W 2510/244

(57) ABSTRACT

A power system and method thereof for charging an electrochemical cell to maintain the cells longevity and/or reduce user's expense is disclosed. The power system may include a traction battery and a controller. The controller may be programmed to initiate a charging command. The charging command may be responsive to a plug-in event and a state-of-charge such that charging is initiated at a future time unless the state-of-charge falls within a capacity-lowering range, region, window, or zone.

### TECHNICAL FIELD

The instant disclosure relates to charging electrochemical cells such as batteries in electrical vehicles. More specifically, the disclosure relates to charging electrochemical cells in a manner that promotes longevity and capacity retention throughout their lifecycle.

### BACKGROUND

Electric vehicles rely on electrochemical cells that store energy. Electric vehicles charge the electrochemical cells by being connected to the power grid for a period of time. Many factors may affect the expense and longevity of these systems.

### SUMMARY

A power system for a vehicle is disclosed. The power system may include a traction battery and a controller. The controller may be programmed to command charging of the traction battery to a target state-of-charge at a future predefined time. The controller may be responsive to a plug-in event and a current state-of-charge. The controller may initiate charging of the traction battery at the future predefined time in response to a plug-in event and the current state-of-charge being outside a predefined state-of-charge range. The controller may also initiate charging of the traction battery before the predefined time as long as the current state-of-charge falls within the predefined state-of-charge range in response to the plug-in event and the current state of charge being within the predefined state-of-charge range.

A vehicle including an electric engine, an electrochemical cell, and a power system is disclosed. The electrochemical cell is configured to power the electric engine. The power system is configured to charge the electrochemical cell during a plug-in event. The power system may delay charging of the electrochemical cell from an immediate time to a future time in response to a state of charge not being in a capacity-lowering zone and may initiate charging of the electrochemical cell before the future time in response to the state-of-charge being within the capacity-lowering zone and continue charging until the state-of-charge is not within the capacity-lowering zone.

A method of smart charging is disclosed. The method includes executing a charging command for charging an electrochemical cell such as a traction battery. The charging command may initiate charging at a future time in response to a plug-in event and a state-of-charge being outside a defined range. The charging command may initiate charging before the future time in response the plug-in event and the state-of-charging being within the defined range such that charging continues at least until the state-of-charge is outside the defined range.

### BRIEF DESCRIPTION OF THE DRAWINGS

FIG. 1 is a schematic diagram of a power system in a vehicle.

FIG. 2 is a capacity retention verse state-of-charge curve.

FIG. 3 is a flow chart of a method of charging an electrochemical cell.

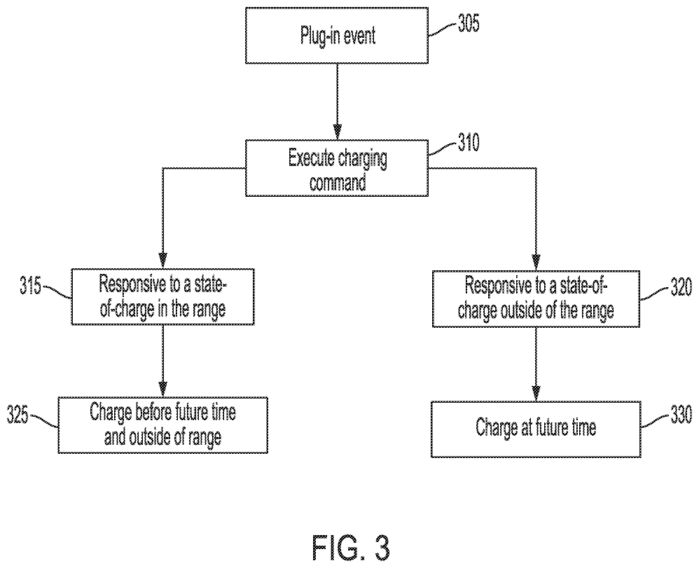

### DETAILED DESCRIPTION

Embodiments of the present disclosure are described herein. It is to be understood, however, that the disclosed embodiments are merely examples and other embodiments can take various and alternative forms. The figures are not necessarily to scale. Some features could be exaggerated or minimized to show details of particular components. Therefore, specific structural and functional details disclosed herein are not to be interpreted as limiting, but merely as a representative basis for teaching one skilled in the art to variously employ the embodiments of the present invention. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

The first definition of an acronym or other abbreviation applies to all subsequent uses herein of the same abbreviation and applies mutatis mutandis to normal grammatical variations of the initially defined abbreviation. Further, unless expressly stated to the contrary, measurement of a property is determined by the same technique as previously or later referenced for the same property.

This disclosure is not limited to the specific embodiments and methods described below, as specific components and/or conditions may vary. Furthermore, the terminology used herein is used only for the purpose of describing particular embodiments and is not intended to be limiting in any way.

It should also be appreciated that integer ranges explicitly include all intervening integers. For example, the integer range 1-10 explicitly includes 1, 2, 3, 4, 5, 6, 7, 8, 9, and 10. Similarly, the range 1 to 100 includes 1, 2, 3, 4 . . . 97, 98, 99, 100. Similarly, when any range is called for, intervening numbers that are increments of the difference between the upper limit and the lower limit divided by 10 can be taken as alternative upper or lower limits. For example, if the range is 1.1. to 2.1 the following numbers 1.2, 1.3, 1.4, 1.5, 1.6, 1.7, 1.8, 1.9, and 2.0 can be selected as lower or upper limits.

Processes executed by a vehicle system or vehicle computing system located in a vehicle may be discussed herein, in certain embodiments, the exemplary processes may be executed by a computing system in communication with a vehicle computing system. Such a system may include, but is not limited to, a wireless device (e.g., and without limitation, a mobile phone) or a remote computing system (e.g., and without limitation, a server) connected through the wireless device. Collectively, such systems may be referred to as vehicle associated computing systems. In certain embodiments, particular components of the vehicle associated computing system may perform particular portions of a process depending on the particular implementation of the system. By way of example and not limitation, if a process has a step of sending or receiving information with a paired wireless device, then it is likely that the wireless device is not performing that portion of the process, since the wireless device would not “send and receive” information with itself. One of ordinary skill in the art will understand when it is inappropriate to apply a particular computing system to a given solution.

Execution of processes may be facilitated through use of one or more controllers or processors working alone or in conjunction with each other and executing instructions stored on various non-transitory storage media, such as, but not limited to, flash memory, programmable memory, hard disk drives, etc. Communication between systems and processes may include use of, for example, Bluetooth, Wi-Fi, cellular communication and other suitable wireless and wired communication.

In the illustrative embodiments discussed herein, an exemplary, non-limiting example of a process performable by a computing system may be shown. With respect to each process, it is possible for the computing system executing the process to become, for the limited purpose of executing the process, configured as a special purpose processor to perform the process. All processes need not be performed in their entirety and are understood to be examples of types of processes that may be performed to achieve elements of the invention. Additional steps may be added or removed from the exemplary processes as desired.

With respect to the illustrative embodiments described in the figures showing illustrative process flows, it is noted that a general-purpose processor may be temporarily enabled as a special purpose processor for the purpose of executing some or all of the exemplary methods shown by these figures. When executing code providing instructions to perform some or all steps of the method, the processor may be temporarily repurposed as a special purpose processor, until such time as the method is completed. In another example, to the extent appropriate, firmware acting in accordance with a preconfigured processor may cause the processor to act as a special purpose processor provided for the purpose of performing the method or some reasonable variation thereof.

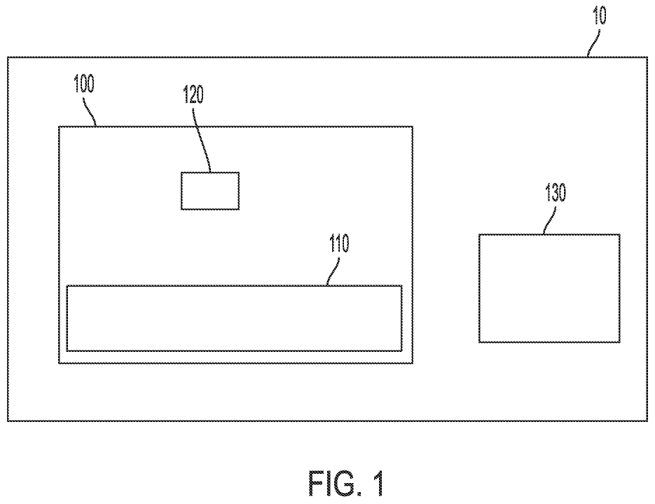

As shown in FIG. 1, a power system 100 is disclosed. The power system 100 may be in a vehicle 10 such as an automobile, motorcycle, train, or watercraft. The power system 100 may include an electrochemical cell 110, a controller 120, and an engine 130. The electrochemical cell 110 may be configured to power the engine 130. The engine 130 may be an electric engine. The engine 130 may convert electrical energy into mechanical energy such that it may propel the vehicle 10 along a surface.

The electrochemical cell 110 may be a battery such as a traction battery. Hereinafter, the terms electrochemical cell and battery may be used interchangeably. The electrochemical cell 110 may be, for example, a lithium-ion battery. The electrochemical cell 110 may include an anode, a cathode, and an electrolyte in contact with the electrodes. The electrochemical cell 110 may also include a separator and/or current collector. The electrochemical cell 110 may, for example, include a nickel (Ni) rich cathode or a nickel-manganese-cobalt (NMC) cathode. The power system 100 may include a plurality of electrochemical cells such as an array or stack.

The controller 120 may be programmed to command charging of the electrochemical cell 110 (e.g., traction battery). The controller 120 may be programmed to command charging of the electrochemical cell 110 to a target state-of-charge by a future predefined time. For example, the target state-of-charge may be 100% and the future predefined time may be 3:00 AM or anytime from 11:00 PM and 7:00 AM. The controller 120 may initiate charging or a charging command upon (i.e., responsive to) receiving a plug-in event. The plug-in event may occur from plugging the power system 100 into an outlet or connecting it to a power grid.

The controller 120 may initiate different charging protocols or charging commands based on parameters such as the expense of electricity, the demand for electricity, the current state-of-charge, the effect on the battery's longevity, user inputs (e.g., desired target charge and desired completion time), or a combination thereof for achieving different goals such as reducing the expense to a user, maximizing the longevity of the battery, or a hybrid thereof. Electricity expense and/or electricity demand may be determined with an electricity rate data such as from a price curve over time, electricity demand date, by communicating with a power grid or power supplying entity, or a combination thereof.

For example, energy demand and electricity expense may be higher during peak hours such as from 7:00 AM to 11:00 PM, or even greater from 3:00 PM to 7:00 PM. Likewise, typical commuting schedules may be focused around the common 9-5 work schedule. Resulting in electric vehicles being charged during peak or high demand periods and at higher expense. To reduce expense and put less stress on the power grid/supply it may be desirable for charging to occur during off-peak hours such as from 11:00 PM to 7:00 AM when the value of electricity is less (e.g., lower electricity rate).

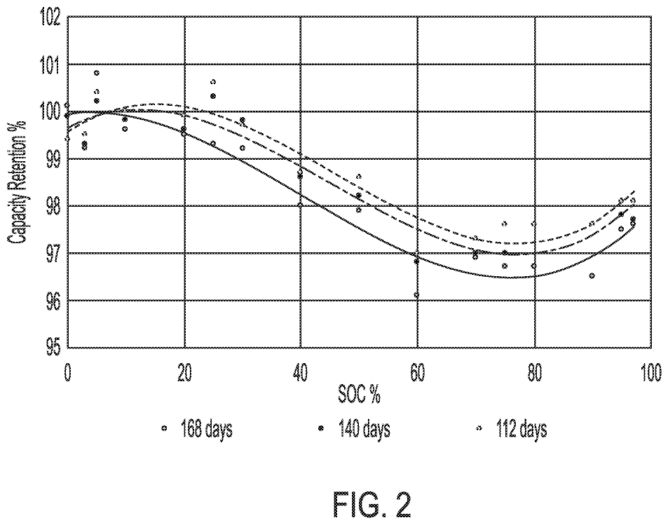

In yet another example, the electrochemical cell 110 may be susceptible to a loss of capacity over time (i.e., fading) such as from calendar aging. This process may be exacerbated by storing the battery with a state-of-charge within specific range, region, window, or zone. For example, fading may be accelerated by storing a battery with a state-of-charge of 50-100%, or 60-90%, or 70-80% as shown in FIG. 2. Lithium-ion batteries such as those with nickel rich cathodes, for example, may be more susceptible to fading or capacity-loss when stored with a state-of-charge of 60-80%, as illustrated by FIG. 2. Batteries of different chemical compositions may have different capacity-lowering ranges, regions, windows, or zones. Accordingly, it may be desirable to minimize the time a battery spends at a specific state-of-charge or state-of-charge range, region, window, or zone.

The controller 120 or charging command may delay charging until a future time to reduce the expense to the user, to maximize the battery's longevity, or may employ a hybrid thereof by following a charging protocol. The protocols may be responsive to one or more parameters such as for example, a plug-in event, state-of-charge, time, energy demand, pricing or a combination thereof.

For example, the capacity of the battery over its lifecycle may be improved by charging protocols that are responsive to a state-of-charge. In at least one variation, the current state-of-charge may fall within a predefined state-of-charge range, region, window, or zone. When the state-of-charge falls with the defined range, region, window, or zone the controller 120 and/or charging command may initiate charging before the future time (e.g., immediately) until the current state-of-charge is no longer within the defined range or so long as the current state-of-charge is within the range. The controller 120 may terminate charging upon reaching a state-of-charge outside the range, reaching the target state-of-charge or achieving a 100% charge.

The predefined range may be associated or correlated with the state-of-charge that is most detrimental to the long-term capacity of the electrochemical cell 110 or battery. This may be determined by analysis and experimentation or based on various parameters such as the type of battery, temperature, age, operating conditions, completion time, desired state-of-charge, or a combination thereof. For example, as shown in FIG. 2, this range may be derived from a capacity retention verse state-of-charge curve. This curve may be obtained by measuring the capacity of a battery before and after various situations (i.e., capacity testing). For example, as shown in FIG. 2, the capacity of batteries may be tested and then stored with a specific state-of-charge (e.g., 0%, 2.5%, 5%, 10%, 20%, 25%, 30%, 40%, 45%, 50%, 60%, 70%, 75%, 80%, 90%, 95%, 97%) for a specific period of time (e.g., 112 days, 140 days, 168 days). After the period of time lapses, the capacity of the batteries may again be measured and compared with the initial capacity before storage at the specific state-of-charge. FIG. 2 illustrates such an analysis with a particular cell at 45° C.

The predefined range may be, for example, 70 to 80%, or more preferably 60 to 90% or even more preferably 50 to 100%. In a refinement, the capacity-lowering range, region, window, or zone may be defined as any state-of-charge that has a capacity retention of less than 97.5%, or more preferably less than 98%, or even more preferably less than 99%. In a refinement, a capacity-lowering range, region, window, or zone may be defined as a capacity retention loss of at least 1%, or more preferably at least 2%, or even more preferably at least 3%. In yet another refinement, the capacity-lowering range, region, window, or zone may be defined as a state-of-charge greater than 70%, or more preferably greater than 60%, or more preferably greater than 50%. The capacity-lowering range, region, window, or zone may also be less than 100%, or more preferably less than 90%, or even more preferably less than 80%.

In another variation, the controller 120 and/or charging command may also discontinue charging until a future time after the state-of-charge is outside the defined range but less than 100%. Once the future time is reached the battery may then be charged to the target state-of-charge (e.g., 100%).

In yet another variation, the current state-of-charge may fall outside the defined range, region, window, or zone. In this situation, the controller 120 and/or charging command may delay and initiate charging until the future time such that the price of electricity is lower and/or the battery is stored at a state-of-charge outside the predefined range, region, window, or zone until the future time.

In still another variation, the controller 120 and/or charging command may initiate charging the battery to a threshold state-of-charge below the predefined range, region, window, or zone before the future time (e.g., immediately) in response to the current state-of-charge being below the predefined range, region, window, or zone. This may occur if it is outside peak demand hours. Charging may then be discontinued and/or delayed until a future time such that the storage time at a state-of-charge in the predefined window is minimized. In a refinement, the threshold point may be a point that has the least capacity-lowering potential such as at a state-of-charge of 15%, as shown in FIG. 2. In yet another refinement, the threshold point may be 50%, or more preferably 40%, or even more preferably 30%. In still another refinement, the threshold point may be defined by the capacity retention, for example, the threshold point may be at a state-of-charge that has a capacity retention of at least 97.5%, or more preferably 98%, or even more preferably at least 99%.

It should be understood that the controller may coordinate or communicate with software or applications such as smart charging applications on different devices such as a server or mobile device for initiating charging commands and/or obtaining information.

A method of smart charging to improve battery longevity and/or reduce a user's expense is disclosed. The method 300 includes executing a charging command 310. The charging command may be responsive to various parameters such as a plug-in event 305, and/or a state-of-charge. The charging command may initiate charging at a future time 330 in response to the plug-in event 305 and a state-of-charge being outside a defined range 320. The charging command may initiate charging before the future time and until the state-of-charge is outside the defined range 325 or at a target state-of-charge in response to a plug-in event and a state-of-charge being within the defined range 315. The charging command may also initiate charging to a threshold state-of-charge that is less than the defined range. Upon reaching the threshold state-of-charge, charging may be discontinued until the future time in response to a plug-in event and that the state-of-charge being less than the defined range. The method 300 may be carried out on the electrochemical cell of a vehicle such as a traction battery as discussed herein. The charging command may charge the battery to a target state-of-charge such as 100% charge at the future time. The target state-of-charge may be outside the defined range. The charging command may also be responsive to energy demand data such as an energy demand curve. The future time may be an off-peak time derived from energy demand data. The off-peak time may be 12 hours, or more preferably 8 hours, or even more preferably 4 hour within a 24-hour period that has the lowest energy demand. For example, the off-peak time or future time may be between 11:00 PM and 7:00 AM

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to strength, durability, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and can be desirable for particular applications.

What is claimed is:

1. A power system for a vehicle comprising:
a traction battery; and
a controller programmed to command charging of the traction battery to a target state-of-charge at a future predefined time such that responsive to a plug-in event and a current state-of-charge being outside a predefined state-of-charge range, the controller initiates charging of the traction battery at the future predefined time to the target state-of-charge, and responsive to the plug-in event and the current state-of-charge being within the predefined state-of-charge range, initiates charging of the traction battery before the future predefined time for as long as the current state-of-charge falls within the predefined state-of-charge range.

2. The power system of claim 1, wherein the target state-of-charge is 100% and the future predefined time is a time when electricity is valued at an off-peak rate.

3. The power system of claim 1, wherein the future predefined time is between 11:00 PM and 7:00 AM.

4. The power system of claim 1, wherein the controller initiates charging of the traction battery to the target state-of-charge at the future predefined time after charging such that the current state-of-charge is outside of the predefined state-of-charge range.

5. The power system of claim 1, wherein the predefined state-of-charge range is derived from a state-of-charge verse capacity curve.

6. The power system of claim 5, wherein the predefined state-of-charge range is 50 to 100%.

7. The power system of claim 5, wherein the predefined state-of-charge range is 60 to 90%.

8. The power system of claim 5, wherein the controller is programmed to command charging of the traction battery such that responsive to a plug-in event and the current state-of-charge being less than the predefined state-of-charge range, the controller initiates charging to and discontinues charging at a threshold state-of-charge less than the predefined state-of-charge range and delays charging from the threshold state-of-charge to the target state-of-charge until the future predefined time.

9. A vehicle comprising:
an electric machine;
an electrochemical cell configured to power the electric machine; and
a power system configured to charge the electrochemical cell during a plug-in event such that:
responsive to a state-of-charge not being in a capacity-lowering zone, the power system delays charging of the electrochemical cell from an immediate time to at a future time; and
responsive to the state-of-charge being within the capacity-lowering zone, the power system initiates charging of the electrochemical cell before the future time until the state-of-charge is not within the capacity-lowering zone.

10. The vehicle of claim 9, wherein the capacity-lowering zone is a state-of-charge greater than 50%.

11. The vehicle of claim 10, wherein the capacity-lowering zone is a state-of-charge less than 100%.

12. The vehicle of claim 10, wherein the capacity-lowering zone is a state-of-charge greater than 60%.

13. The vehicle of claim 12, wherein the capacity-lowering zone is a state-of-charge greater than 70%.

14. The vehicle of claim 13, wherein the power system is configured to charge the electrochemical cell to a threshold state-of-charge, responsive to the plug-in event and the current state-of-charge being less than the capacity-lowering zone and discontinue charging until the future time, wherein the threshold state-of-charge is less than the capacity-lowering zone.

15. A method of smart charging comprising:
executing a charging command to
initiate charging at a future time responsive to a plug-in event and a state-of-charge being outside a defined range; and
initiate charging before the future time, responsive to the plug-in event and the state-of-charge being within the defined range and charging until the state-of-charge is outside the defined range.

16. The method of claim 15, wherein the charging command initiates charging to a threshold state-of-charge less than the defined range and discontinues charging at the threshold state-of-charge until the future time responsive to the plug-in event and the state-of-charge being less than the defined range.

17. The method of claim 15, wherein the charging command is executed on a vehicle.

18. The method of claim 15, wherein charging command charges to a target state-of-charge that the future time.

19. The method of claim 15, wherein the charging command is responsive to energy demand data such that the future time is an off-peak time derived from the energy demand data.

20. The method of claim 15, wherein the future time is between 11:00 PM and 7:00 AM.
